(19) United States
(12) Patent Application Publication
(10) Pub. No.: US 2026/0369533 A1
(43) Pub. Date: Nov. 19, 2026

(54) SYSTEM AND METHOD FOR PROCESSING A WAFER EDGE

(71) Applicant: TEL Manufacturing and Engineering of America, Inc., Chaska, MN (US)

(72) Inventors: Junichi Kitano, Chaska, MN (US); Shuji Suzuki, Chaska, MN (US)

(21) Appl. No.: 19/391,016

(22) Filed: Nov. 17, 2025

Related U.S. Application Data
(60) Provisional application No. 63/806,058, filed on May 15, 2025.

(51) Int. Cl. H01J 37/32; H01J 37/317; H10P 50/28; H10W 74/01

(52) U.S. Cl. CPC H01J 37/32761; H01J 37/3174; H01J 37/32385; H01J 37/32715; H10P 50/283; H10W 74/01; H01J 37/321; H01J 2237/31755; H01J 2237/31766; H01J 2237/334

(57) ABSTRACT

A method for semiconductor device processing, wherein the method includes receiving a wafer including a substrate, a device layer formed over a front side of a central device region of the substrate, and a protection layer formed over sides of a circumferential edge region of the substrate, the edge region contiguously surrounding the device region, the protection layer including a front portion radially overlapping a front surface of the device layer, the overlap leaving a central portion of the front surface exposed, the device layer including a first thickness, and the front portion of the protection layer including a varying second thickness; and scanning a directed particle beam relative to the wafer, the scanning being restricted to the front portion, the scanning removing a material of the protection layer and being stopped after matching the second thickness of the front portion to the first thickness of the device layer.

### CROSS-REFERENCE TO RELATED APPLICATIONS

This application claims the benefit of U.S. Provisional Application No. 63/806,058, filed on May 15, 2025, which application is hereby incorporated herein by reference.

### TECHNICAL FIELD

The present invention relates generally to a system and method for semiconductor device processing, and, in particular embodiments, to a system and method for processing a wafer edge.

### BACKGROUND

Integrated circuit (IC) devices reduce cost and complexity of an electronic system while increasing the system’s performance and reliability by forming, in one densely packed monolithic structure, a circuit performing multiple system functions. Various circuit components, connected with contacts, metal lines, and vias, are formed by processing a batch of semiconductor wafers through a fabrication flow comprising a sequence of patterning levels. The monolithic structure gets constructed as a stack of layers as, at each patterning level, a layer in the wafer is patterned using lithography techniques, where copies of a radiation pattern are printed in an array over each wafer before new layers are deposited for the next level of patterning. At the end of the fabrication flow, an array of IC devices is fabricated in each wafer. Integrating multiple system functions in one IC device provides a benefit of reducing a number of devices needed for the system, but the benefit is traded off for higher processing complexity, hence a higher unit cost of the IC. Thus, to optimize system cost, IC devices are produced in separate categories such as logic, memory, high voltage, photonic, and micro electro-mechanical systems (MEMS) ICs, so each IC fabrication flow uses compatible materials and processes in a reasonable number of patterning levels. The various IC devices of an electronic system may have to transmit and receive signals through long wires at a high cost in speed and power consumption. The cost may be mitigated using a three-dimensional (3D) stacked IC concept, where IC devices on different wafers are coupled by wafer bonding techniques, thus eliminating the need for long wires between the ICs and high-power input-output driver circuits. But there are challenges to achieving a high yield with wafer bonding. Thus, further process innovations to prepare wafer surfaces for bonding with high yield are desired.

### SUMMARY

A method for semiconductor device processing, wherein the method includes receiving a wafer including a substrate, a device layer formed over a front side of a central device region of the substrate, and a protection layer formed over sides of a circumferential edge region of the substrate, the edge region contiguously surrounding the device region, the protection layer including a front portion radially overlapping a front surface of the device layer, the overlap leaving a central portion of the front surface exposed, the device layer including a first thickness, and the front portion of the protection layer including a varying second thickness; and scanning a directed particle beam relative to the wafer, the scanning being restricted to the front portion, the scanning removing a material of the protection layer and being stopped after matching the second thickness of the front portion to the first thickness of the device layer.

A method for semiconductor device processing, wherein the method includes receiving a wafer including a substrate, a device layer formed over a front side of a central device region of the substrate, and a protection layer formed over sides of a circumferential edge region of the substrate, the edge region contiguously surrounding the device region, the protection layer including a front portion radially overlapping a front surface of the device layer, the overlap leaving a central portion of the front surface exposed; and performing a location specific processing (LSP) to remove material from the front portion by moving the wafer along a trajectory in a reference plane of the wafer, the trajectory being selected to scan a scan area of the front portion through a directed particle beam, the selecting restricting the LSP to the front portion, where, at each location of the trajectory, the LSP sets a removal rate specific to coordinates of the location in the reference plane.

A processing tool, wherein the tool is a location specific etch tool including an etch chamber including a substrate holder to hold a wafer to be processed; a beam generator configured to provide a directed particle beam for etching; a wafer scanner coupled to the etch chamber, the wafer scanner configured to move the substrate holder relative to the beam at a scan rate along a desired trajectory while the wafer is being held by the substrate holder, where the moving along the trajectory scans the beam over an annular scan area proximate a periphery of a front side of the wafer; and electronic circuitry including: a transceiver to receive data measured at a plurality of locations in the scan area, the data being a property of an edge protection layer of the wafer, and transmit control signals to the beam generator and the wafer scanner; a memory storing the measured data and a program; a processor to execute the program, the program when executed, outputs, for each location of the trajectory, a location specific removal rate based on the measured data; and a controller to generate the control signals transmitted by the transceiver, the control signals setting, for each location of the trajectory, a location specific processing condition based on the location specific removal rate.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1A illustrates a cross-sectional view of an incoming wafer, in accordance with some embodiments;

FIG. 1B illustrates a zoomed-in cross-sectional view of a portion of the wafer illustrated in FIG. 1A;

FIG. 2 illustrates a cross-sectional view of a schematic of a processing tool, in accordance with some embodiments;

FIG. 3A illustrates a cross-sectional view of a wafer after removing a portion of a protection layer, which is fully filling a recess over an edge region of the wafer, in accordance with some embodiments;

FIG. 3B illustrates a cross-sectional view of a wafer after removing a portion of a protection layer, which is partially filling a recess over an edge region of the wafer, in accordance with some embodiments;

FIG. 4 illustrates a flowchart summarizing a method for semiconductor device processing, in accordance with some embodiments; and

FIG. 5 illustrates a flowchart summarizing a location specific processing method for semiconductor device processing, in accordance with some embodiments.

### DETAILED DESCRIPTION OF ILLUSTRATIVE EMBODIMENTS

This disclosure relates to a processing tool and method for processing a wafer’s edge region in an integrated circuit (IC) fabrication flow. In various embodiments, the processing comprises performing an etch process to remove material from a portion of a protection layer formed over sides of a region near a periphery of the wafer. The etching is performed in an etch tool using a beam etching technique. The protection layer is formed to leave a central region of the wafer exposed while covering the peripheral region. Generally, an incoming wafer to the etch tool has been processed for the central region to have a substantially flat front surface, but a topography of a surface of a front portion of the protection layer has a nonuniform height. The variation in the height of the front portion of the protection layer may make an annular area near the periphery of the wafer unsuitable for wafer bonding. The etch processes described in this disclosure is applicable to shaping the surface of the front portion of the protection layer to reduce the height variation in order to extend the area of a front side of the wafer suitable for wafer bonding. The front side refers to the side of the wafer to be bonded to a different wafer, a side opposite the front side is referred to as back side, and a side connecting the front side to the back side circumferentially along the periphery of the wafer is referred to as outer side. Wafer bonding (i.e., wafer-to-wafer (W2W) bonding) is used for three-dimensional (3D) sequential integration and 3D stacked IC devices. The embodiments described in this disclosure may provide advantages of a larger area suitable for bonding and an improved process yield by reducing edge defectivity during bonding. As described in this disclosure, these advantages result from the etch processing reducing variations in height in the topography of the front portion of the protection layer, thus increasing a radius of a central circular flat portion of the front side of the wafer to extend further towards the periphery. Accordingly, fewer random void defects are expected to form near the edge. Void defects reduce local bond strength between two surfaces and may even result in delamination. Furthermore, surface topography affects bond wave velocity. Thus, variations in height (e.g., a bump or a divot) along the periphery may cause radially asymmetric bond wave propagation, resulting in higher strain in the bonded wafers. By reducing the height variations, a more radially symmetric bond wave propagation may be achieved during bonding, which reduces mechanical stress and improves process yield.

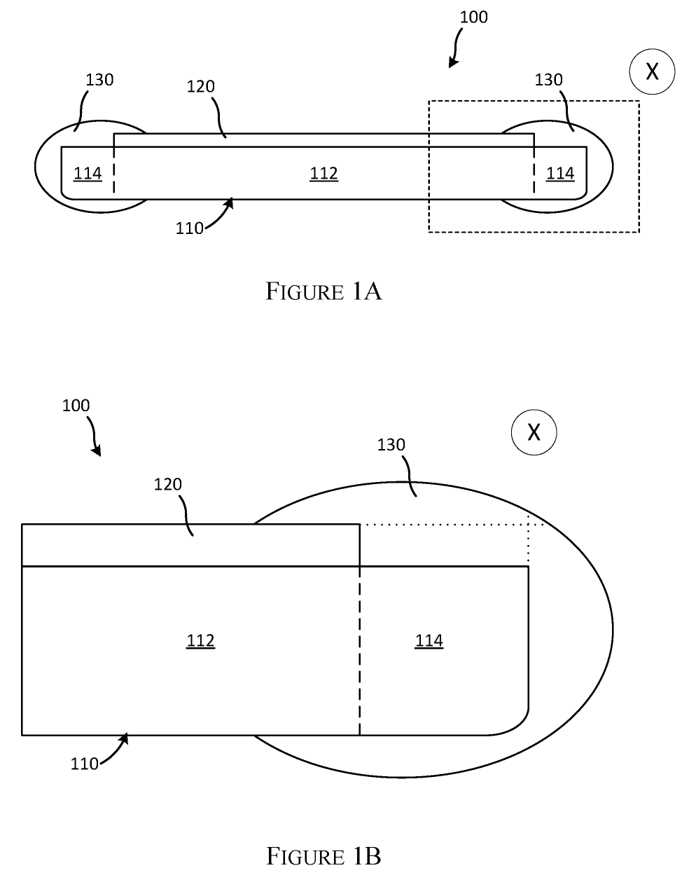

FIG. 1A illustrates a cross-sectional view of a wafer 100 that may be an incoming wafer for an example embodiment of the etch processing mentioned above, and FIG. 1B shows a zoomed-in view of a portion of the wafer 100 closer to the periphery of the wafer 100 (marked as X). As illustrated in FIG. 1A, the wafer 100 comprises a substrate 110, a device layer 120, and a protection layer 130.

A starting material for the substrate 110 may comprise a semiconductor, for example, silicon, germanium, GaAs, InAs, a semiconductor alloy, or the like. The device layer 120 may comprise metal, dielectric, and semiconductor layers. The protection layer 130 may comprise a dielectric (e.g., silicon oxide, silicon nitride, silicon oxynitride, and silicon oxycarbide).

The semiconductor substrate 110 has a central device region 112 over which the device layer 120 has been formed. Contiguously surrounding the device region 112 is a circumferential edge region 114 of the substrate 110. The device region 112 and the device layer 120 may include structures for electronic components (e.g., transistors, resistors, and capacitors) as well as some metal lines and contacts. Note that the incoming wafer 100 has been processed for the device layer 120 to have a substantially flat front surface.

During various deposition and etch steps, residues may accumulate in the edge region 114 outside the device region 112. Particles from this residue may migrate toward the center and contaminate the electronic components. Also, a rounded shape of the substrate 110 near the periphery (attributed to chemical-mechanical polishing (CMP)) can make the edge region 114 prone to chipping during a backgrind process done for wafer thinning subsequent to bonding. However, an edge trim may remove most of the rounded portion of the front side by removing material from near the periphery of the substrate. Furthermore, the edge trim removes some of the edge defects formed in earlier process steps. Generally, the edge trim process uses a blade or a diamond abrasive tape to remove material from the front side and may expose the starting semiconductor material. In general, the blade or the tape may be tilted to create, for example, a tapered surface. However, in the example embodiment, a vertical trim has been done, forming a vertical side of the device layer 120 and a recessed edge region 114. It is noted that the rounded shape of the surface of the substrate 110 near the periphery is present in a back side of the edge region 114, but the rounded portion has been practically removed from a front side of the edge region 114 by the edge trimming to form a relatively flat front surface of the edge region 114, as seen clearly in FIG. 1B. A process integration option of edge trimming before wafer bonding has been used in the example illustrated in FIGS. 1A and 1B. For this option, care has to be taken to prevent particles generated by the trimming from contaminating the device layer 120 by using, for example, a center-to-edge flow of de-ionized water during the edge trimming.

After the edge trimming has completed shaping the front surface of the edge region of the substrate 110, the protection layer 130 of the wafer 100 has been formed over sides of a peripheral region of the wafer 100, as illustrated in FIGS. 1A and 1B. The protection layer 130 may be deposited near the peripheral region of the wafer 100 in a special deposition step, commonly referred to as a bevel deposition step, using a suitable deposition technique that deposits material selectively covering the desired peripheral area.

The protection layer 130 may be formed using, for example, a plasma deposition tool designed for depositing material using plasma confined to a toroidal region around a central region. A plasma-enhanced chemical vapor deposition (PECVD) process performed with such a plasma tool is referred to here as a toroidal plasma deposition process. The toroidal plasma deposition process may be performed to deposit material over an annular outer area of the wafer 100. The surface over which the protection layer 130 is formed excludes a central circular area on the front side and, likewise, on a back side of the wafer 100. The radii of the excluded areas of the front side and the back side of the wafer 100 may be independently and precisely controlled by positioning upper and lower exclusion zone rings, respectively, to deposit material over a desired continuous portion of a surface near the periphery of wafer 100. In the example embodiment in FIG. 1B, it is seen that a roughly circular boundary of the edge region 114 with the device layer 120 is included in the annular outer area of the wafer 100 over which the protection layer 130 is deposited. This may be achieved by the toroidal plasma deposition process positioning the upper exclusion zone rings to configure the deposition tool to have a deposition zone, which includes the boundary of the edge region 114 with the device layer 120 on one side and the edge of the wafer 100 on the other side.

Location specific deposition techniques using beam processing may also be used to form the protection layer 130. In beam processing, a beam may be scanned relative to the wafer 100 over the peripheral region of the wafer 100 where deposition is desired. The protection layer 130 may be formed using, for example, a laser beam of a laser chemical vapor deposition (LCVD) process, or a gas cluster beam (GCB) of a GCB-assisted deposition process. In LCVD, the laser beam is scanned in presence of a precursor gas in the chamber. The laser provides energy for chemical reactions with the precursor gas to produce the material being deposited. The photonic energy may get directly absorbed by the precursor gas (a technique known as photolytic LCVD) or be used to create a local hot spot in the wafer 100 that induces the chemical reactions (a technique known as pyrolytic LCVD). Typical spot sizes of the laser beam for LCD are in the micrometer range compared to typically larger (millimeter range) spot sizes for the GCB. Similar to LCVD, in GCB assisted deposition, the beam is scanned over the peripheral region of the wafer 100. But, unlike in LCVD, here, the beam, directed to a spot on the wafer 100, provides the precursor gas since the GCB comprises clusters of precursor gas molecules. Additionally, in beam processing, the deposition angle may be adjusted (e.g., by tilting the wafer 100 during scanning) to deposit material where it is needed, including on the front, back or side of the wafer 100.

In various embodiments, the protection layer 130 covers a circumferential outer side and a front side of the edge region 114 of the substrate 110. The protection layer 130 further covers an annular portion of the front surface and the vertical side of the device layer 120 including the boundary of the edge region 114 with the device layer 120. Note that the front portion of the protection layer 130 radially overlaps the device layer 120 but leaves a roughly circular central portion of the front surface of the device layer 120 exposed. Typically, the overlap is relatively small, a width of the overlap being less than a width of the edge region 114 of the substrate 110 but greater than zero. The width of the edge region 114 may be from about 2 mm to about 10 mm.

In the example embodiment, the surface covered by the protection layer 130 further includes an annular portion of a back side of the substrate 110, as illustrated in FIGS. 1A and 1B. In some other embodiment, the plasma deposition tool may be configured such that the material of the protection layer 130 is not deposited on the back side of the substrate 110.

In various embodiments, the device layer 120 has a relatively constant first thickness, and the front portion of the protection layer 130 has a varying second thickness. The first thickness and the second thickness are vertical distances measured from the front surface of the edge region 114. As mentioned above, after the device layer 120 has been formed and the substrate 110 has been prepared for forming the protection layer 130 by performing, for example, the edge trimming described above, the front surface of the edge region 114 is disposed below the front surface of the device layer 120. Thus, the front surface of the edge region 114 forms a bottom surface of a recess, a depth of the recess being the first thickness. The protection layer 130 with the front portion having a varying second thickness is then deposited using, for example, the toroidal plasma deposition process described above.

Note that, a perimeter of the flat portion of the front side of the incoming wafer 100 is a circumference of the roughly circular exposed central portion of the front surface of the device layer 120. The etch processing shifts the perimeter radially outward to be located at some distance beyond the boundary of the edge region 114 with the device layer 120, referred to as a radial extension in this disclosure. The radial extension depends on a deposition thickness of the deposition process used to form the protection layer 130, the radial extension increasing with increasing deposition thickness, as explained further below. After the etch processing, a width of the flat portion of the front side of the wafer 100 is increased from a diameter of the circular exposed central portion of the front surface of the device layer 120 to a sum of the diameter of the device layer 120 and two times the radial extension.

In the example embodiment illustrated in FIG. 1A, the varying second thickness of the front portion of the protection layer 130 above each location of the front surface of the edge region 114 exceeds the depth of the recess. This indicates that the deposition thickness of the deposition process used to form the protection layer 130 may be greater than the depth of the recess. Accordingly, the front portion of the protection layer 130 fully fills the recess and extends above the front surface of the device layer 120, as illustrated in FIGS. 1A and 1B. In other words, a variable height of the front portion of the protection layer 130 relative to the front surface of the device layer 120 may increase radially outward from zero at a perimeter of the circular exposed portion of the front surface of the device layer 120 and go through a peak value, the height remaining above zero (i.e., the second variable second thickness is greater than the first thickness) all the way to the outer side of the edge region 114 of the substrate 110, as seen from the positions of the dotted lines in FIG. 1B.

In some other embodiment, the varying second thickness of the front portion of the protection layer 130 may be less than the depth of the recess. This indicates that the deposition thickness of the deposition process used to form the protection layer 130 may be less than the depth of the recess. In such embodiments, the front portion of the protection layer 130 partially fills the recess. The variable height of the front portion of the protection layer 130 relative to the front surface of the device layer 120 is zero at the perimeter of the exposed portion of the front surface of the device layer 120 and increases radially outward in the region where the front portion of the protection layer 130 overlaps the device layer 120 and continue to increase till the height goes through a peak value. However, as the radial distance is increased further, the height could drop below zero (i.e., the second thickness becomes less than the first thickness) before reaching the outer side of the edge region 114. In other words, the height remains above zero up to some radial distance from the boundary of the device layer 120 and the edge region 114. A length of this radial distance is a width of an annular region beyond the boundary of the device layer 120 and the edge region 114, where a surface of the front portion of the protection layer 130 is above the flat front surface of the device layer 120. As described further below, the width of this annular region becomes the radial extension after the etch processing for removing material from the front portion of the protection layer 130 is completed.

Embodiments of etch processes in this disclosure may remove a portion of the protection layer 130 to reduce undesirable variations in height in the topography of the front side of the wafer 100. However, without the protection layer 130 covering the vertical side of the device layer 120, the front side of the edge region 114, and the circumferential outer side of the edge region 114, the electronic components of the wafer 100 may be vulnerable to contamination (e.g., metal contamination) through the vertical sides of the device layer 120 during subsequent processing. Additionally, in 3D sequential integration, active electronic devices may be fabricated subsequent to bonding in the wafer bonded to wafer 100. For example, in some embodiments using wafer bonding to fabricate sequential complementary field effect transistor (sCFET), the integration flow may comprise fabricating nFET devices in wafer 100 prior to bonding, and, subsequent to bonding, fabricating pFET devices in the wafer bonded to wafer 100. Particles (e.g., metal particles) from the wafer 100 could contaminate front-end-of-line (FEOL) tools used in the fabrication of the pFET devices, resulting in unacceptably high yield loss. Here, the protection layer 130 can help prevent such contamination in the FEOL tools. Thus, irrespective of whether the protection layer 130 fully fills the recess or partially fills the recess, any etch process in the embodiments in this disclosure that may remove a portion of the protection layer 130 is configured to retain a portion of the protection layer 130 covering the vertical side of the device layer 120, the front side of the edge region 114, and the circumferential outer side of the edge region 114.

The processing in the embodiments in this disclosure may be utilized for shaping a surface of a front side of an incoming wafer such as the incoming wafer 100 as part of preparing the surface for wafer bonding. The processing for shaping the surface comprises performing an etch process to remove a portion of a protection layer such as the protection layer 130 formed over an outer area of the incoming wafer 100. It is desired that the height of the front portion of the protection layer 130 (relative to the front surface of the device layer 120) be reduced to zero by removing material from the portion of the protection layer 130, where the height is greater than zero. The etch processing would thus achieve the radial extension described above, which may improve bonding quality and enhance process yield by reducing undesirable variations in height in the topography of the front portion the protection layer 130. As seen from FIG. 1A and the position of the dotted lines in FIG. 1B, the surface of the protection layer 130 is above the surface of the device layer 120 (i.e., the height is greater than zero) in a roughly annular region having a width equal to a sum of the width of the overlap and the radial extension. It is desirable to restrict the etching to this annular portion of the protection layer 130 to avoid damaging the device layer 120. In some embodiments, where the protection layer 130 is relatively thin there is also a possibility of undesirably exposing the front surface of the edge region 114 or the circumferential outer side of the edge region 114, resulting in a risk of metal contamination from the exposed areas during a process step performed subsequent to bonding, as explained above.

The front side of the incoming wafer comprises a device layer formed over a central device region of substrate such as the device layer 120 of the device region 112 of the substrate 110 of the incoming wafer 100. The device region is surrounded by an edge region such as the edge region 114 of the substrate 110. As described above, a front portion of the protection layer covers a front surface of the edge region and overlaps a portion of the device layer along a boundary of the device layer with the edge region, leaving a central region exposed. The front portion of the protection layer has a variable height, thus a variable thickness above the edge region. The device layer has a flat front surface, a central circular portion of which is thus exposed by the protection layer. This exposed portion is then the flat front surface of the incoming wafer. In various embodiments, the method of reducing the height variations of the front portion the protection layer results in radially extending the flat region of the front surface of the wafer.

In various embodiments, the method comprises performing etch processes that use a beam etching technique. Generally, in beam etching techniques, material is removed from a wafer-to-be-etched by physical and chemical interactions between particles in the beam with the material near the wafer surface being exposed to the particle beam. The area of the surface that gets exposed to the beam is determined by controlling a relative motion of the beam and the surface. The relative motion may be achieved by moving the desired area of the wafer surface through the beam (using, e.g., a wafer scanner) or by moving the beam over the desired area of the wafer surface (using, e.g., an electromagnetic scanner for a beam comprising charged particles) or a combination of both. For generality, we refer to this motion simply as a relative movement.

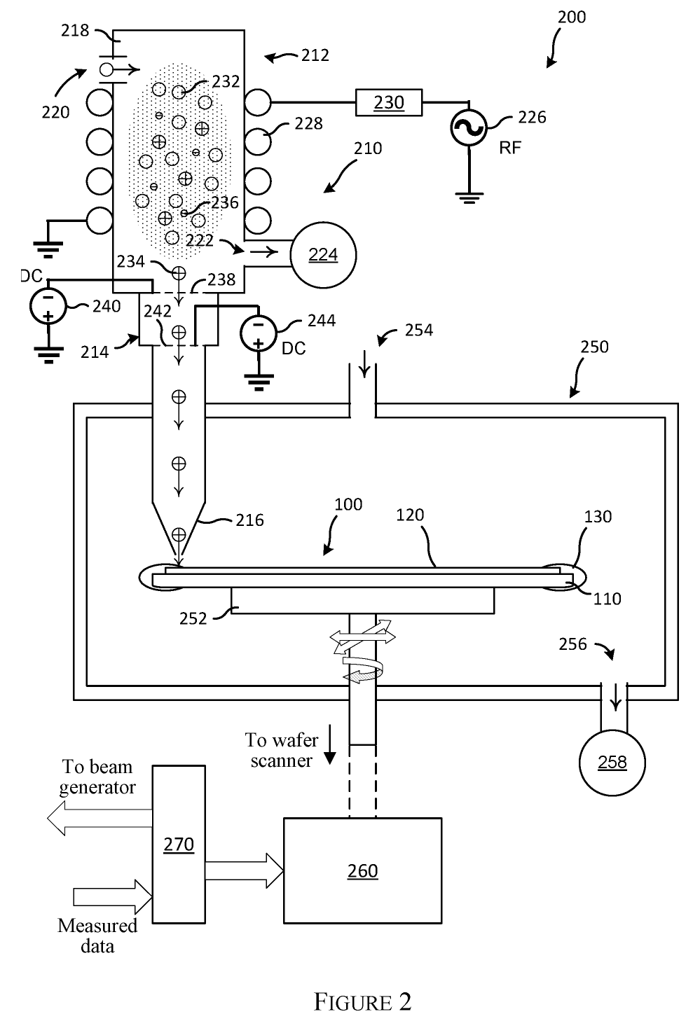

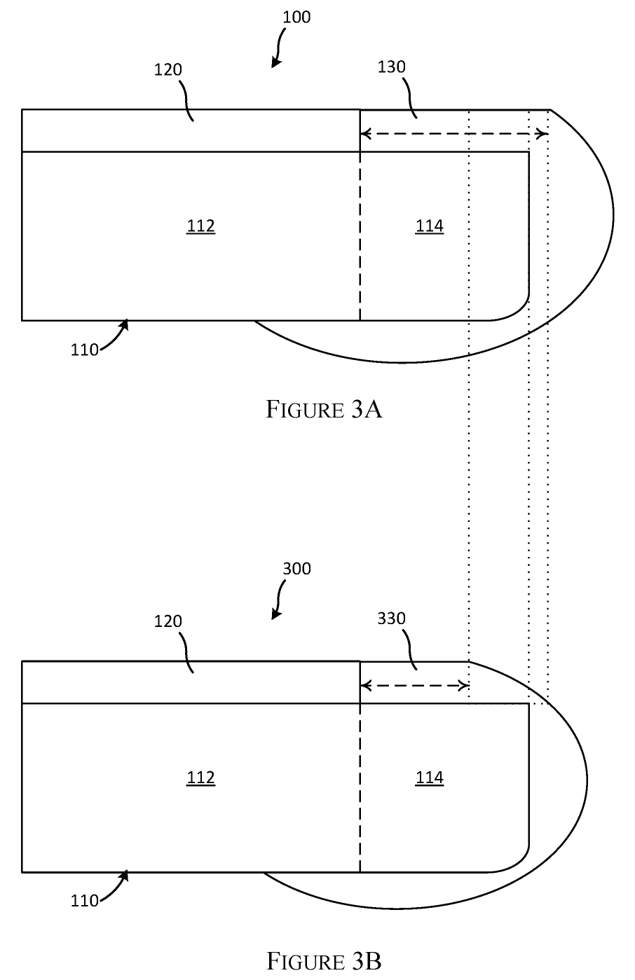

Embodiments of the method are described with reference to a processing tool illustrated schematically in FIG. 2, where the incoming wafer is processed in an etch chamber of the processing tool. The etching comprises scanning a directed particle beam relative to the wafer to remove material from the front portion of the protection layer. In various embodiments, it is desirable to restrict the etching to the annular portion of the protection layer 130, as explained above. Thus, the scanning may be restricted to a scan area in the front portion of the protection layer. However, as explained further below, due to process variations, a portion of the scan area may spill over into the exposed circular central portion of the front surface of the device layer 120 or go beyond the outer side of the wafer 100. As described further below, the removal rate may be controlled by setting a process condition comprising controllable process parameters of the etch process. Cross-sectional views of the wafer after the etch processing is complete are illustrated in FIGS. 3A and 3B.

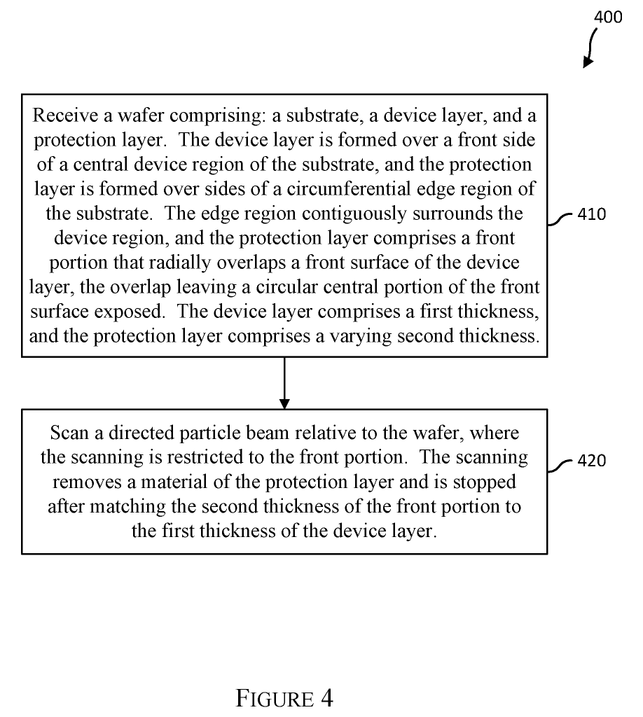

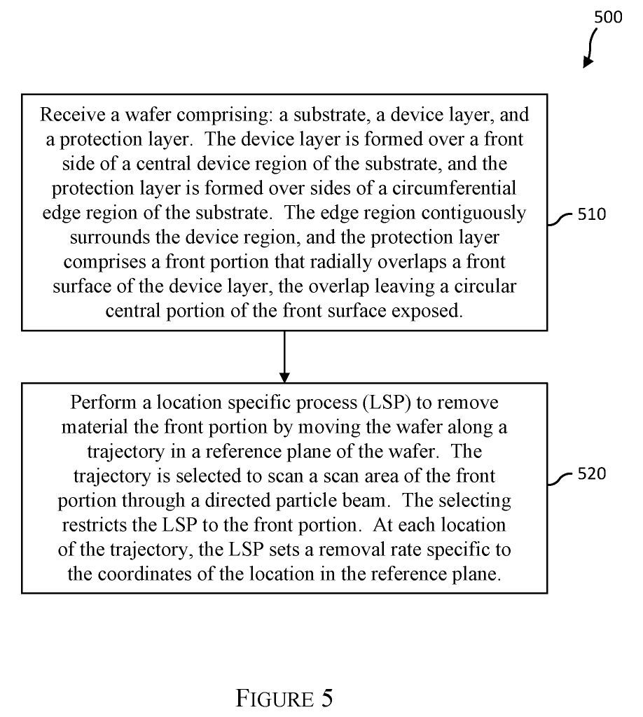

The method is summarized with reference to a flowchart illustrated in FIG. 4. In some embodiments, the etch process may be a location specific processing (LSP), where the removal rate may be a variable removal rate based on measurements of a property (e.g., thickness) obtained from a plurality of locations in the front portion of the protection layer. In etching using LSP, the removal rate may be varied during scanning, depending on the coordinates of the scan area where the particle beam is located. The method using LSP is summarized with a flowchart illustrated in FIG. 5.

FIG. 2 illustrates a cross-sectional view of a schematic of an example processing tool 200 comprising a beam generator 210 configured to generate a beam of particles comprising ions and radicals. The ratio of ions to radicals may be adjusted to generate an “ion beam” having a relatively high ion-to-radical ratio or a “radical beam” having a relatively high radical-to-ion ratio. The processing tool 200 is an etch tool for executing an etch process using the ion or radical beam for removing material by scanning the ion or radical beam relative to a wafer being processed. The beam generator 210 in this example comprises a remote plasma source 212, a particle extractor 214, and a nozzle 216.

The remote plasma source 212 may comprise a vacuum chamber 218 coupled to a gas-flow system to flow a gas through the vacuum chamber 218 using, for example, a gas inlet 220, a gas outlet 222, and a vacuum pump 224 coupled to the gas outlet 222. The gas flowing through the vacuum chamber 218 may be ionized by coupling, for example, radio frequency (RF) power to generate a gas discharge plasma. The RF power may be supplied by an RF source 226 to an electrode 228 coupled to plasma in the vacuum chamber 218 via an impedance matching network 230. The RF source 226 may be, for example, an adjustable power continuous wave RF power source operating at a frequency of, say, 13.56 MHz. In this example, the electrode 228 is a helical coil winding around an outside wall of a dielectric window of the vacuum chamber 218, as illustrated in the schematic in FIG. 2. In this configuration, an RF signal applied to the electrode 228 may induce an ionizing electromagnetic field that may ignite and sustain the plasma in the vacuum chamber 218. Plasma, generated in this configuration, is referred to as inductively coupled plasma (ICP), and the configuration is referred to as an ICP mode. A typical gas discharge plasma comprises a majority of neutral particles 232 and a roughly equal number of positively charged ions 234 and negatively charged free electrons 236. The neutral particles 232 include highly reactive neutral radicals that have electrons in excited states of the atom.

Since the remote plasma source 212 can supply ions and radicals, the etching may be performed chemically by radicals or physically by energetic ions by appropriately configuring the plasma source 212.

In some embodiments, the beam generator 210 may be configured to generate an ion beam. In some other embodiments, the beam generator 210 may be configured to generate a radical beam. For specificity, in the embodiment of the processing tool 200 in FIG. 2, the beam of particles generated by the beam generator 210 for etching is shown to be an ion beam.

The ion beam in FIG. 2 is initiated in the particle extractor 214 and transported to an etch chamber 250 of the processing tool 200. The etch chamber 250 is another vacuum chamber, different from the vacuum chamber 218 of the remote plasma source 212 (hence the name remote plasma). Positively charged ions 234 may be extracted from the plasma by an array of mesh electrodes biased negatively relative to a plasma potential to attract the positively charged ions 234. The particle extractor 214 illustrated in the schematic in FIG. 2, is seen to have two mesh electrodes indicated by dashed lines biased by two independent DC sources of the particle extractor 214. A mesh electrode, referred to as a source electrode 238, is inserted at an interface between the vacuum chamber 218 of the remote plasma source and the particle extractor 214. Typically, the mesh electrodes are designed to have a high transparency to particles intended to be transported through the mesh electrodes. The source electrode 238 is biased with a first DC bias source 240. Another mesh electrode, referred to as an extraction electrode 242, may be inserted further downstream of the flow of ions and biased by a second DC bias source 244. The extraction electrode 242 may be biased to be more negative than the source electrode 238 to accelerate the ions to a desired average kinetic energy. The average kinetic energy may be an adjustable parameter controlled by the DC bias voltages.

In some other embodiment, the particle beam generated by the beam generator 210 may be a radical beam, also initiated in the particle extractor 214 and transported to the etch chamber 250. The radical beam has a relatively lower ratio of ions to radicals compared to the ratio of ions to radicals in the ion beam. The lower ion-to-radical ratio may be achieved by adjusting the bias voltages output from the first DC bias source 240 and the second DC bias source 244 to repel the positively charged ions. The neutral radicals are transported by diffusion; hence the radical flux is relatively insensitive to the DC bias voltages. In various embodiments, the radicals may comprise reactants such as fluorine, chlorine, or oxygen, depending on the specific application. For example, in one embodiment, fluorine radicals may be used to chemically etch a layer of silicon. Here, the ions do not react chemically with the material being etched by the radical beam.

In some embodiments, the particle beam may include radicals and ions extracted from the plasma that cooperatively remove material from the front portion of the protection layer 130.

At the end of the particle extractor 214, the extracted particles may enter a nozzle 216 disposed, for example, in the etch chamber 250, as illustrated in FIG. 2. The nozzle 216 may be designed to focus the incoming particles to a directed particle beam comprising a flux of ions or radicals extracted from the remote plasma of the remote plasma source 212. In some embodiments, the particle flux may be an adjustable parameter. Various process parameters may be used to adjust the particle flux, for example, the RF power, RF frequency, the DC bias voltages, and geometrical parameters of the nozzle 216.

In some embodiments, the beam width may be an adjustable parameter controlled by the geometrical parameters of the nozzle 216. In various embodiments, a beam width of the ion beam may be from about 0.5 mm to about 10 mm. As mentioned above, in most applications, the width of the edge region 114 may be from about 2 mm to about 10 mm and the overlap of the protection layer 130 over the device layer 120 is small compared to the width of the edge region 114. Using a beam width much larger than the width of the edge region 114 may have a risk of damaging the device layer 120. Thus, even though the beam generator (e.g., the beam generator 210) can generate wider beams (e.g., beam width in the range from 0.5 mm to about 40 mm), it is desirable to use a narrow beam and scan the particle beam relative to the wafer to expose the area to be etched, if needed.

The etch chamber 250 comprises a substrate holder 252 to hold a wafer to be processed, such as the wafer 100, as illustrated in FIG. 2. The wafer 100 in FIG. 2, comprising the substrate 110, the device layer 120, and the protection layer 130 is same as the wafer 100 described above with reference to FIG. 1A. An ambiance in the etch chamber 250 may be controlled by flowing a gas, for example, an inert gas at a low pressure through the etch chamber 250. The gas flow may be achieved using, for example, a gas inlet 254, a gas outlet 256, and a vacuum pump 258 coupled to the gas outlet 256 of the etch chamber 250.

The substrate holder 252 may be moved by a wafer scanner 260 of the processing tool 200 coupled to the etch chamber 250, as indicated schematically in FIG. 2. In general, the wafer scanner 260 is configured to move the substrate holder 252 relative to the directed particle beam at a desired scan rate along a desired trajectory while the wafer 100 is being held by the substrate holder 252. As indicated by several solid arrows in FIG. 2, the wafer scanner 260 can move the substrate holder 252 along orthogonal directions (x and y-directions) as well as rotate the substrate holder 252 azimuthally in a plane of the wafer 100. In addition, the wafer scanner 260 can tilt the substrate holder 252 relative to the particle beam while moving the substrate holder in the plane of the wafer 100. The example wafer scanner 260 used in the embodiments in this disclosure is described in detail in US Patent 11,587,760 B2, which is included in its entirety by reference with this application. However, it is understood that some other wafer scanner may also be used. It is also understood, that in some embodiments, the particle beam may be moved relative to the substrate holder 252.

In the embodiments in this disclosure, the scanning is restricted to the front portion of the protection layer 130. As mentioned above, width of the overlap is less than a width of the edge region 114, and the width of the edge region 114 may be from about 2 mm to about 10 mm. The beam width, which is in the range of 0.5 mm to 10 mm, is comparable to a width of the annular front portion of the protection layer 130. Thus, although we say that the scanning is restricted to the front portion of the protection layer 130, it is understood that a portion of the particle beam may spill over into the exposed circular central portion of the front surface of the device layer 120 or go beyond the outer side of the wafer 100.

The beam generator 210 described above is for performing an etch process, referred to as a partial plasma etch (PPE) process in this disclosure. With the PPE process, the etching is done on a wafer, such as the wafer 100, using a particle beam comprising a flux of ions or radicals, such as the particle beam described above; the particles are extracted from a remote plasma source, such as the remote plasma source 210, and directed through a nozzle, such as the nozzle 216, toward the wafer (e.g., the wafer 100), with the wafer positioned on a substrate holder, such as the substrate holder 252, to scan the front portion through the particle beam using a wafer scanner, such as the wafer scanner 260.

In some other embodiments, a flux of ions extracted from a remote plasma may be directed toward the wafer using an electromagnetic collimator. The beam generator may then comprise electromagnetic lenses instead of a nozzle to focus the ion beam. The respective etch process is referred to as a focused ion beam (FIB) etch process in this disclosure.

In yet some other embodiments, the particle beam generated by the beam generator may be a gas cluster beam (GCB). The GCB may be used to remove material from the front portion of the protection layer (such as the protection layer 130). The beam generator may first generate neutral gas clusters, which are clusters of about 1000 to about 10000 gas molecules loosely bound by van der Waals forces. The neutral cluster gas may be formed by adiabatic cooling as gas is released through a nozzle into a vacuum chamber. The neutral gas clusters are moved through an ionizer, where the clusters may be partially ionized by a beam of free electrons directed toward the flow of the cluster gas. As the electrons collide with the clusters, the cluster gas may be partially ionized, commonly resulting in positively charged ions. The number of ions in a single cluster, hence the charge of an ionized cluster may vary. The ionized cluster gas may be collimated by electromagnetic lenses to form a GCB directed toward the wafer to be processed in the etch chamber. Etching by scanning the wafer through the GCB is referred to as a GCB etch process in this disclosure.

Independent of which type of beam generator is being used, the method for removing material of the protection layer is scanning the directed particle beam relative to the wafer being processed. The particle beam may be interacting physically with the surface to remove material. In some embodiments, there may be a chemical component to the interaction between the particles of the beam and the surface of the scan area of the wafer 100. Generally, scanning the beam has an effect of smoothening the surface by sputtering material off a bump, a portion of which may get redeposited in a divot.

As mentioned above, the device layer 120 of the incoming wafer 100 has a relatively constant first thickness, and the front portion of the protection layer 130 has a varying second thickness. The first thickness and the second thickness are vertical distances measured from the front surface of the edge region 114. The etching is for reducing the height variation in the topography of the front portion of the protection layer 130 described above. Thus, the scanning may be stopped after matching the second thickness of the front portion to the first thickness of the device layer. As mentioned above, the scanning may be restricted to the front portion.

In some embodiments, matching the second thickness of the front portion to the first thickness of the device layer comprises restricting the scanning to a substantially annular scan area of the front portion of the protection layer 130 such that, after the scanning, a vertical position (i.e., a vertical height) of a surface of the scan area relative to the flat exposed portion of the front surface of the device layer is in a specified range around 0 nm. The specified range may be an acceptably small number, for example from about -1 nm to about 1 nm in order to achieve a substantially flat surface in the scan area, thereby extending the flat portion of the front surface of the incoming wafer 100 beyond the boundary of the device layer 120 with the edge region 114.

In some embodiments, matching the second thickness of the front portion to the first thickness of the device layer comprises restricting the scanning to a scan area, where the scan area is a portion of the edge region where the second thickness is greater than the first thickness. The scanning is performed such that, after the scanning, a difference between the second thickness and the first thickness is in a specified range around 0 nm. Again, the specified range may be an acceptably small number, for example from about -1 nm to about 1 nm in order to achieve a substantially flat surface in the scan area, thereby extending the flat portion of the front surface of the incoming wafer 100 beyond the boundary of the device layer 120 with the edge region 114. It should be noted that it is intended for the scanning to clear the material of the protection layer 130 covering the overlap area, hence, in various embodiments, the scan area includes the overlap of the protection layer 130 with the device layer 120.

In either case, a predetermined scan time may be used to match the second thickness to the first thickness. The scan time may be predetermined by evaluating cross-sectional images obtained from test wafers.

Cross-sectional views of the wafer 100 having a protection layer 130 and another wafer 300 having a protection layer 330 are illustrated in FIGS. 3A and 3B, respectively. The cross-sectional views are shown after the etch processing is completed. The device layer 120 and the substrate 110 are same for both wafer 100 and wafer 300. Prior to etching, a protection layer 330 in wafer 300 was formed to be thinner than the protection layer 130 in wafer 100. The thicknesses were selected such that the protection layer 130 fully fills the recess above the front surface of the edge region 114, whereas the protection layer 330 partially fills the recess above the front surface of the edge region 114. Once the etch processing is completed, using either of the stopping criteria described above, it is seen that the flat portion of the front side of wafer 100 and the flat portion of the front side of wafer 300 has been radially extended beyond the boundary of the device layer 120 with the edge region 114. However, because of the thinner protection layer 330 had partially filled the recess, the wafer 300 has achieved a smaller radial extension compared to the radial extension of the wafer 100, as seen from the dashed double arrows and the vertical dotted lines between the cross-sectional views illustrated in FIGS. 3A and 3B.

FIG. 4 illustrates a flowchart summarizing the method 400, which includes the example embodiments described above.

As indicated in box 410, the method 400 comprises receiving a wafer (e.g., wafer 100) comprising a substrate (e.g., substrate 110), a device layer (e.g., device layer 120) formed over a front side of a central device region (e.g., device region 112) of the substrate, and a protection layer (e.g., protection layer 130) formed over sides of a circumferential edge region (e.g., edge region 114) of the substrate. The edge region contiguously surrounds the device region, and the protection layer comprises a front portion that radially overlaps a front surface of the device layer, the overlap leaving a circular central portion of the front surface exposed. The device layer comprises a first thickness, and the front portion of the protection layer comprises a varying second thickness.

As indicated in box 420, the method 400 further comprises scanning a directed particle beam relative to the wafer, where the scanning is restricted to the front portion of the protection layer, as explained above. As described above, the scanning removes a material of the protection layer and is stopped after matching the second thickness of the front portion to the first thickness of the device layer.

As mentioned above, the removal rate, hence the scan time, may be controlled by setting a process condition comprising controllable process parameters of the etch process. In some embodiments, the process conditions for the etch processes may be based on measured data, where a property of the front portion of the protection layer 130, for example, a thickness of the front portion of the protection layer 130 is measured. Referring back to FIG. 2, the processing tool 200 may be tasked to receive the measured data, determine a removal rate based on the data, and control the beam generator 210 and the wafer scanner 260 accordingly. Thus, the processing tool 200 further comprises electronic circuitry 270 to perform these tasks. The electronic circuitry 270 of the processing tool 200 comprises a transceiver, a memory, a processor, and a controller.

The transceiver is configured to receive data measured at a plurality of locations in the scan area, the data being a property of the protection layer of the wafer, and to transmit control signals to the beam generator 210 and the wafer scanner 260 to control operation of the beam generator 210 and the wafer scanner 260.

The memory may be configured to store the measured data and a program to be executed by the processor. The processor is configured to execute the program. When executed, the program outputs a removal rate for the processing tool 200 based on the measured data.

In embodiments where the etch process is the PPE process performed in the processing tool 200, the removal rate depends on various process parameters, including the ion or radical flux and the wafer scan rate. Thus, the removal rate of the etch process may be adjusted by configuring the beam generator 210 and the wafer scanner 260. to provide a particle flux and a scan rate appropriate for the desired removal rate. The beam generator 210 and the wafer scanner 260 may be configured using control signals generated by the controller and transmitted by the transceiver in the electronic circuitry 270 of the processing tool 200. In some embodiment, the removal rate may be adjusted by adjusting the particle flux. The beam generator 210 can be configured by the controller of the electronic circuitry 270 to provide the desired particle flux. Likewise, in some embodiment, the removal rate may be adjusted by adjusting the scan rate. The wafer scanner 260 can be configured by the controller of the electronic circuitry 270 to provide the desired scan rate.

The processing tool 200 may be a location specific etch tool that may be configured to execute an etch process that is an LSP. As mentioned above, an LSP is a process where the processing at any location of the wafer being processed may depend on coordinates of the location. An advantage of LSP is that the process may be dynamically adjusted for areal nonuniformities in the wafer. For example, a nonuniform thickness distribution of a layer being etched may be compensated for by increasing a removal rate in a region where the thickness is greater and vice versa. As a result, thickness uniformity is improved for the processed wafer. In wafer bonding, it is desirable that the bond wave propagation has radial symmetry. Thus, azimuthal variations in the surface topography is undesirable. Variations in surface topography with azimuthal angle may be evaluated with thickness measurements performed a priori at a plurality of locations. An etch process that uses beam etching with LSP can utilize the measured data and provide location specific removal rates based on the measurements during the scanning by appropriately varying a process parameter which may be used to control the removal rate.

Performing the LSP to remove material from the front portion of the protection layer (e.g., the protection layer 130) comprises moving the wafer along a trajectory in a reference plane of the incoming wafer (e.g., the incoming wafer 100), where the trajectory is selected to scan a scan area of the front portion through the directed particle beam generated by the beam generator 210. Thus, selecting the trajectory restricts the LSP to the front portion of the protection layer. At each location of the trajectory, the LSP sets a removal rate specific to coordinates of the location in the reference plane. Accordingly, the measured data may comprise, for example, thickness data of the protection layer obtained from a plurality of locations across the scan area.

In some embodiments, the scan area is a ring-shaped area which could be a substantially annular shaped region, wherein an inner boundary of the ring is the perimeter of the exposed circular central portion of the front surface of the device layer, and an outer boundary of the ring is located over the edge region, wherein a variable thickness of the front portion of the protection layer is greater than a thickness of the device layer. The ring-shaped scan area may be scanned using, for example, a circular or spiral trajectory.

In some embodiments of the method, the LSP may create a mapping (e.g., a model such as a mathematical model) that maps the coordinates of each location of the trajectory to the removal rate for that location to be set by the LSP. The mapping may be created by the processor executing instructions coded in the program (stored in the memory) and based on the measured values and the coordinates of the respective locations (retrieved from the memory). Using the mapping, the processor may output a location specific removal rate for a plurality of locations along the trajectory. The plurality of location specific removal rates and respective locations are provided to the controller of the electronic circuitry 270. The controller may be configured to generate control signals to set process conditions for the beam generator 210 and the wafer scanner 260 for the processing tool 200 to achieve the removal rate specified for each location along the trajectory.

The removal rate may be controlled by various controllable process parameters of the etch process, as mentioned above. In general, the process condition set by the control signals from the controller may comprise values of any subset of the set of controllable process parameters.

In some embodiments, the LSP sets the removal rate specific to coordinates of the location in the reference plane by setting a scan rate for the location. The scan rate for the location is a speed with which the wafer is moved when the particle beam intersects the wafer at the coordinates of the location. Exposure time per unit area at a location exposed to the particle beam is inversely proportional to the scan rate. Thus, a higher scan rate gives a lower removal rate for a particle beam with a constant particle flux.

In some embodiments, the LSP sets the removal rate specific to coordinates of the location in the reference plane by setting a particle flux for the location. The particle flux for the location is an arrival rate of particles of the particle beam when the particle beam intersects the wafer at the coordinates of the location. A higher particle flux increases the removal rate.

In some embodiments, the LSP may set the removal rate specific to coordinates of the location in the reference plane by setting a combination of the scan rate and the particle flux for the location.

FIG. 5 illustrates a flowchart summarizing the method 500, which includes the embodiments of the example method using LSP to etch a portion of the protection layer, as described above.

As indicated in box 510, the method 500 comprises receiving a wafer (e.g., wafer 100) comprising a substrate (e.g., substrate 110), a device layer (e.g., device layer 120) formed over a front side of a central device region (e.g., device region 112) of the substrate, and a protection layer (e.g., protection layer 130) formed over sides of a circumferential edge region (e.g., edge region 114) of the substrate. The edge region contiguously surrounds the device region, and the protection layer comprises a front portion that radially overlaps a front surface of the device layer, the overlap leaving a circular central portion of the front surface exposed.

As indicated in box 520, the method 500 further comprises performing an LSP to remove material from the front portion of the protection layer by moving the wafer along a trajectory in a reference plane of the wafer. The trajectory is selected to scan a scan area of the front portion through a directed particle beam. The selecting restricts the LSP to the front portion. At each location of the trajectory, the LSP sets a removal rate specific to the coordinates of the location in the reference plane.

Example embodiments of the invention are described below. Other embodiments can also be understood from the entirety of the specification as well as the claims filed herein.

Example 1. A method for semiconductor device processing, wherein the method includes receiving a wafer including a substrate, a device layer formed over a front side of a central device region of the substrate, and a protection layer formed over sides of a circumferential edge region of the substrate, the edge region contiguously surrounding the device region, the protection layer including a front portion radially overlapping a front surface of the device layer, the overlap leaving a central portion of the front surface exposed, the device layer including a first thickness, and the front portion of the protection layer including a varying second thickness; and scanning a directed particle beam relative to the wafer, the scanning being restricted to the front portion, the scanning removing a material of the protection layer and being stopped after matching the second thickness of the front portion to the first thickness of the device layer.

Example 2. The method of example 1, further including, prior to receiving the wafer, forming the protection layer, the protection layer covering a continuous portion of a surface of the wafer including a circular boundary of the edge region with the device layer, the portion including: a circumferential outer side and a front side of the edge region; and an annular portion of a front surface and a vertical side of the device layer.

Example 3. The method of one of examples 1 or 2, where the continuous portion further includes an annular portion of a back side of the substrate.

Example 4. The method of one of examples 1 to 3, where, prior to forming the protection layer, performing an edge trim, the performing the edge trim including removing material from a front side of the edge region of the substrate.

Example 5. The method of one of examples 1 to 4, where matching the second thickness of the front portion to the first thickness of the device layer includes scanning the particle beam relative to the wafer for a predetermined scan time.

Example 6. The method of one of examples 1 to 5, where matching the second thickness of the front portion to the first thickness of the device layer includes restricting the scanning to an annular scan area of the front portion; and where, after the scanning, a vertical position of a surface of the scan area relative to the exposed portion of the front surface of the device layer is in a specified range around 0 nm.

Example 7. The method of one of examples 1 to 6, where the specified range is from -1 nm to 1 nm.

Example 8. The method of one of examples 1 to 7, where matching the second thickness of the front portion to the first thickness of the device layer includes restricting the scanning to a scan area, the scan area including a portion of the edge region where the second thickness is greater than the first thickness; and where, after the scanning, a difference between the second thickness and the first thickness is in a specified range around 0 nm.

Example 9. The method of one of examples 1 to 8, where the specified range is from -1 nm to 1 nm.

Example 10. The method of one of examples 1 to 9, where a width of the radial overlap of the protection layer is greater than zero and less than a width of the edge region of the substrate.

Example 11. The method of one of examples 1 to 10, where the scanning includes utilizing a partial plasma etch (PPE) process, where the particle beam includes a flux of ions extracted from a remote plasma and directed through a nozzle toward the wafer, with the wafer being positioned to scan the front portion through the particle beam.

Example 12. The method of one of examples 1 to 11, where the scanning includes utilizing a partial plasma etch (PPE) process, where the particle beam includes a flux of radicals extracted from a remote plasma and directed through a nozzle toward the wafer, with the wafer being positioned to scan the front portion through the particle beam.

Example 13. The method of one of examples 1 to 12, where the scanning includes utilizing a focused ion beam (FIB) etch process, where the particle beam includes a flux of ions extracted from a remote plasma and directed toward the wafer using an electromagnetic collimator, with the wafer being positioned to scan the front portion through the particle beam.

Example 14. The method of one of examples 1 to 13, where the scanning includes utilizing a gas cluster beam (GCB) etch process, where the particle beam includes a GCB directed toward the wafer with the wafer being positioned to scan the front portion through the particle beam.

Example 15. A method for semiconductor device processing, wherein the method includes receiving a wafer including a substrate, a device layer formed over a front side of a central device region of the substrate, and a protection layer formed over sides of a circumferential edge region of the substrate, the edge region contiguously surrounding the device region, the protection layer including a front portion radially overlapping a front surface of the device layer, the overlap leaving a central portion of the front surface exposed; and performing a location specific processing (LSP) to remove material from the front portion by moving the wafer along a trajectory in a reference plane of the wafer, the trajectory being selected to scan a scan area of the front portion through a directed particle beam, the selecting restricting the LSP to the front portion, where, at each location of the trajectory, the LSP sets a removal rate specific to coordinates of the location in the reference plane.

Example 16. The method of example 15, where the scan area is a ring-shaped area, where an inner boundary of the ring is a perimeter of the exposed central portion of the front surface of the device layer, and an outer boundary of the ring is located over the edge region, where a variable thickness of the front portion of the protection layer is greater than a thickness of the device layer.

Example 17. The method of one of examples 15 or 16, further including, prior to performing the LSP, measuring a property of the front portion of the protection layer at a plurality of measurement locations across the scan area; and based on the measured values, mapping the coordinates of each location of the trajectory to the removal rate to be set for that location by the LSP.

Example 18. The method of one of examples 15 to 17, where the measuring a property includes measuring a thickness.

Example 19. The method of one of examples 15 to 18, where, at each location of the trajectory, the LSP sets a removal rate specific to coordinates of the location in the reference plane by setting a scan rate for the location, the scan rate for the location being a speed with which the wafer is moved when the particle beam intersects the wafer at the coordinates of the location.

Example 20. The method of one of examples 15 to 19, where, at each location of the trajectory, the LSP sets a removal rate specific to coordinates of the location in the reference plane by setting a particle flux for the location, the particle flux for the location being an arrival rate of particles of the particle beam when the particle beam intersects the wafer at the coordinates of the location.

Example 21. A processing tool, wherein the tool is a location specific etch tool including an etch chamber including a substrate holder to hold a wafer to be processed; a beam generator configured to provide a directed particle beam for etching; a wafer scanner coupled to the etch chamber, the wafer scanner configured to move the substrate holder relative to the beam at a scan rate along a desired trajectory while the wafer is being held by the substrate holder, where the moving along the trajectory scans the beam over an annular scan area proximate a periphery of a front side of the wafer; and electronic circuitry including: a transceiver to receive data measured at a plurality of locations in the scan area, the data being a property of an edge protection layer of the wafer, and transmit control signals to the beam generator and the wafer scanner; a memory storing the measured data and a program; a processor to execute the program, the program when executed, outputs, for each location of the trajectory, a location specific removal rate based on the measured data; and a controller to generate the control signals transmitted by the transceiver, the control signals setting, for each location of the trajectory, a location specific processing condition based on the location specific removal rate.

Example 22. The processing tool of example 21, where the location specific processing condition is the scan rate, where the scan rate at each location of the trajectory, depends on coordinates of the location.

Example 23. The processing tool of one of examples 21 or 22, where the location specific processing condition is a flux of particles in the particle beam, where the particle flux at each location of the trajectory, depends on coordinates of the location.

Example 24. The processing tool of one of examples 21 to 23, where the beam generator includes: a remote plasma source, the remote plasma source configured to sustain a plasma including ions and radicals; a particle extractor; and a nozzle; and where the directed particle beam is a radical beam including radicals extracted from the remote plasma by the particle extractor and directed through the nozzle.

Example 25. The processing tool of one of examples 21 to 24, where the beam generator includes: a remote plasma source; an ion extractor; and an electromagnetic collimator; and where the directed particle beam is a focused ion beam including ions extracted from the remote plasma by the ion extractor and directed by the electromagnetic collimator.

Example 26. The processing tool of one of examples 21 to 25, where the beam generator includes: a gas cluster source; an ionizer; and an electromagnetic collimator; and where the directed particle beam is a gas cluster beam (GCB) including ionized gas clusters directed by the electromagnetic collimator.

Example 27. A processing tool, wherein the tool is a location specific etch tool including an etch chamber comprising a substrate holder to hold a wafer to be processed; a beam generator configured to provide a directed particle beam for etching; a wafer scanner coupled to the etch chamber, the wafer scanner configured to move the substrate holder relative to the beam at a scan rate along a desired trajectory while the wafer is being held by the substrate holder, where the moving along the trajectory scans the beam over an annular scan area proximate a periphery of a front side of the wafer; and electronic circuitry configured to generate and transmit control signals to the beam generator and the wafer scanner, the control signals setting, for each location of the trajectory, a location specific processing condition based on a desired location specific removal rate.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments. For example, embodiments described in FIGS. 1A-5 may be combined in whole or part together in different embodiments. The processor and memory discussed in various embodiments may be one or more components as in multiple processors and memories. It is therefore intended that the appended claims encompass any such modifications or embodiments.

What is claimed is:

1. A method for semiconductor device processing comprising:
receiving a wafer comprising a substrate, a device layer formed over a front side of a central device region of the substrate, and a protection layer formed over sides of a circumferential edge region of the substrate, the edge region contiguously surrounding the device region, the protection layer comprising a front portion radially overlapping a front surface of the device layer, the overlap leaving a central portion of the front surface exposed, the device layer comprising a first thickness, and the front portion of the protection layer comprising a varying second thickness; and
scanning a directed particle beam relative to the wafer, the scanning being restricted to the front portion, the scanning removing a material of the protection layer and being stopped after matching the second thickness of the front portion to the first thickness of the device layer.

2. The method of claim 1, further comprising, prior to receiving the wafer, forming the protection layer, the protection layer covering a continuous portion of a surface of the wafer including a circular boundary of the edge region with the device layer, the portion comprising:
a circumferential outer side and a front side of the edge region; and
an annular portion of a front surface and a vertical side of the device layer.

3. The method of claim 2, wherein the continuous portion further comprises an annular portion of a back side of the substrate.

4. The method of claim 2, wherein, prior to forming the protection layer, performing an edge trim, the performing the edge trim comprising removing material from a front side of the edge region of the substrate.

5. The method of claim 1, wherein matching the second thickness of the front portion to the first thickness of the device layer comprises scanning the particle beam relative to the wafer for a predetermined scan time.

6. The method of claim 1,
wherein matching the second thickness of the front portion to the first thickness of the device layer comprises restricting the scanning to a scan area, the scan area comprising a portion of the edge region where the second thickness is greater than the first thickness; and
wherein, after the scanning, a difference between the second thickness and the first thickness is in a specified range around 0 nm.

7. The method of claim 1, wherein the scanning comprises utilizing a partial plasma etch (PPE) process, wherein the particle beam comprises a flux of ions extracted from a remote plasma and directed through a nozzle toward the wafer, with the wafer being positioned to scan the front portion through the particle beam.

8. The method of claim 1, wherein the scanning comprises utilizing a partial plasma etch (PPE) process, wherein the particle beam comprises a flux of radicals extracted from a remote plasma and directed through a nozzle toward the wafer, with the wafer being positioned to scan the front portion through the particle beam.

9. The method of claim 1, wherein the scanning comprises utilizing a gas cluster beam (GCB) etch process, wherein the particle beam comprises a GCB directed toward the wafer with the wafer being positioned to scan the front portion through the particle beam.

10. A method for semiconductor device processing comprising:
receiving a wafer comprising a substrate, a device layer formed over a front side of a central device region of the substrate, and a protection layer formed over sides of a circumferential edge region of the substrate, the edge region contiguously surrounding the device region, the protection layer comprising a front portion radially overlapping a front surface of the device layer, the overlap leaving a central portion of the front surface exposed; and
performing a location specific processing (LSP) to remove material from the front portion by moving the wafer along a trajectory in a reference plane of the wafer, the trajectory being selected to scan a scan area of the front portion through a directed particle beam, the selecting restricting the LSP to the front portion, wherein, at each location of the trajectory, the LSP sets a removal rate specific to coordinates of the location in the reference plane.

11. The method of claim 10, wherein the scan area is a ring-shaped area, wherein an inner boundary of the ring is a perimeter of the exposed central portion of the front surface of the device layer, and an outer boundary of the ring is located over the edge region, wherein a variable thickness of the front portion of the protection layer is greater than a thickness of the device layer.

12. The method of claim 10, further comprising,
prior to performing the LSP, measuring a property of the front portion of the protection layer at a plurality of measurement locations across the scan area; and
based on the measured values, mapping the coordinates of each location of the trajectory to the removal rate to be set for that location by the LSP.

13. The method of claim 12, wherein the measuring a property comprises measuring a thickness.

14. The method of claim 10, wherein, at each location of the trajectory, the LSP sets a removal rate specific to coordinates of the location in the reference plane by setting a scan rate for the location, the scan rate for the location being a speed with which the wafer is moved when the particle beam intersects the wafer at the coordinates of the location.

15. The method of claim 10, wherein, at each location of the trajectory, the LSP sets a removal rate specific to coordinates of the location in the reference plane by setting a particle flux for the location, the particle flux for the location being an arrival rate of particles of the particle beam when the particle beam intersects the wafer at the coordinates of the location.

16. A processing tool, the tool being a location specific etch tool comprising:
an etch chamber comprising a substrate holder to hold a wafer to be processed;
a beam generator configured to provide a directed particle beam for etching;
a wafer scanner coupled to the etch chamber, the wafer scanner configured to move the substrate holder relative to the beam at a scan rate along a desired trajectory while the wafer is being held by the substrate holder, wherein the moving along the trajectory scans the beam over an annular scan area proximate a periphery of a front side of the wafer; and
electronic circuitry comprising:
a transceiver to receive data measured at a plurality of locations in the scan area, the data being a property of an edge protection layer of the wafer, and transmit control signals to the beam generator and the wafer scanner;
a memory storing the measured data and a program;
a processor to execute the program, the program when executed, outputs, for each location of the trajectory, a location specific removal rate based on the measured data; and
a controller to generate the control signals transmitted by the transceiver, the control signals setting, for each location of the trajectory, a location specific processing condition based on the location specific removal rate.

17. The processing tool of claim 16, wherein the location specific processing condition is the scan rate, wherein the scan rate at each location of the trajectory, depends on coordinates of the location.

18. The processing tool of claim 16,
wherein the beam generator comprises:
a remote plasma source, the remote plasma source configured to sustain a plasma comprising ions and radicals;
a particle extractor; and
a nozzle; and
wherein the directed particle beam is a radical beam comprising radicals extracted from the remote plasma by the particle extractor and directed through the nozzle.

19. The processing tool of claim 16,
wherein the beam generator comprises:
a remote plasma source;
an ion extractor; and
an electromagnetic collimator; and
wherein the directed particle beam is a focused ion beam comprising ions extracted from the remote plasma by the ion extractor and directed by the electromagnetic collimator.

20. The processing tool of claim 16,
wherein the beam generator comprises:
a gas cluster source;
an ionizer; and
an electromagnetic collimator; and
wherein the directed particle beam is a gas cluster beam (GCB) comprising ionized gas clusters directed by the electromagnetic collimator.

21. A processing tool, the tool being a location specific etch tool comprising:
an etch chamber comprising a substrate holder to hold a wafer to be processed;
a beam generator configured to provide a directed particle beam for etching;
a wafer scanner coupled to the etch chamber, the wafer scanner configured to move the substrate holder relative to the beam at a scan rate along a desired trajectory while the wafer is being held by the substrate holder, wherein the moving along the trajectory scans the beam over an annular scan area proximate a periphery of a front side of the wafer; and
electronic circuitry configured to generate and transmit control signals to the beam generator and the wafer scanner, the control signals setting, for each location of the trajectory, a location specific processing condition based on a desired location specific removal rate.
.
